(19) United States
(12) Patent Application Publication
(10) Pub. No.: US 2013/0208253 A1
(43) Pub. Date: Aug. 15, 2013

(54) REFLECTIVE PHOTOLITHOGRAPHY APPARATUS HAVING CONTROL MIRROR MODULE

(71) Applicant: Samsung Electronics Co., Ltd., (US)

(72) Inventor: WOO-SEOK SHIM, OSAN-SI (KR)

(73) Assignee: SAMSUNG ELECTRONICS CO., LTD., SUWON-SI (KR)

(21) Appl. No.: 13/764,817

(22) Filed: Feb. 12, 2013

(30) Foreign Application Priority Data
Feb. 13, 2012 (KR) 10-2012-0014398

(51) Int. Cl. G03F 7/20

(52) U.S. Cl. CPC G03F 7/702
USPC 355/67

(57) ABSTRACT

A reflective photolithography system includes an extreme ultraviolet light source, an illumination mirror system that reflects light generated by the light source, a blinder through which a portion of the reflected light is allowed to pass, a reticle stage equipped with a reflective reticle which receives the light passing through the blinder, and a projection mirror system configured that projects light reflected from the reflective reticle onto a wafer on a wafer stage. The illumination mirror system includes a control mirror module at its downstream end with respect to the optical axis of the apparatus. The control mirror module has a plurality of unit control mirrors which divide the light so as to illuminate a number of domains and such that the intensity of the light can be varied among the domains.

### PRIORITY STATEMENT

This application claims priority under 35 U.S.C. §119 to Korean Patent Application No. 10-2012-0014398 filed on Feb. 13, 2012, the disclosure of which is hereby incorporated by reference in its entirety.

### BACKGROUND

The inventive concept relates to photolithography. More particularly, the inventive concept relates to a reflective photolithography exposure apparatus.

Photolithography is a process by which patterns, e.g., circuit patterns, can be transcribed onto a substrate such as a semiconductor wafer. In photolithography, an image of a pattern of a reticle is transferred to a photosensitive film (photoresist) on the substrate in an exposure process using light from a specific light source. Conventional transmissive types of reticles comprise a substrate and the pattern of the reticle is provided at a surface of the substrate. The substrate of the reticle is transparent with respect to the exposure light, and the pattern of the reticle may be opaque or partially opaque with respect to the exposure light. In an exposure process using a transmissive type of reticle, the light from the light source is directed through the reticle and onto the photoresist such that the photoresist is exposed to a virtual image of the reticle pattern. Then the photoresist is developed to remove either the exposed or unexposed portions thereof, thereby forming a photoresist pattern. Finally, underlying material is etched using the photoresist pattern as a mask. As a result, a pattern corresponding to that of the reticle is formed.

Recently, extreme ultraviolet light (EUV) has been considered for use in photolithography because its short wavelength lends itself to the forming of ultrafine patterns of semiconductor devices. Photolithography using EUV requires a reflective reticle because most materials will absorb EUV instead of transmitting it due to the relatively short wavelength of EUV.

### SUMMARY

According to an aspect of the inventive concept, there is provided a reflective photolithography apparatus that includes a light source, an illumination mirror system having a plurality of illumination mirrors and a control mirror module, a reticle stage, a projection mirror system including a projection mirror, and a wafer stage, and in which the control mirror module includes a plurality of unit control mirrors having reflective surfaces, respectively, that are each adjustable.

According to another aspect of the inventive concept, there is provided a reflective photolithography apparatus that includes a light source that generates extreme ultraviolet light, an illumination mirror system disposed in the apparatus to receive light generated by the light source and reflect the light, a blinder disposed in the apparatus to receive the light reflected by the illumination mirror system and configured to allow one portion of the light received thereby to pass therethrough and block the remainder of the light received thereby, a reticle stage configured to support a reflective reticle at the bottom thereof and positioned relative to the blinder such that the portion of the light passing through the blinder is received by the reticle supported by the reticle stage and reflected thereby back through the blinder, a projection mirror system disposed in the apparatus to receive the light reflected from the reflective reticle mounted on the reticle stage and passing back through the exposure slit and project the light in a given direction in the apparatus, and a wafer stage disposed in the apparatus in the path of the light projected by the projection mirror system such that a wafer mounted on the wafer stage will receive the light projected by the projection mirror system, and in which the illumination mirror system includes a control mirror module at an end thereof closest to the blinder with respect to the direction in which light is transmitted from the illumination mirror system in the apparatus. The control mirror module has a plurality of unit control mirrors which divide the light so as to illuminate a number of domains, respectively, and the unit control mirrors are adjustable to vary the intensity of the light among the domains.

According to still another aspect of the inventive concept, there is provided a reflective photolithography apparatus that includes a light source, a reticle stage, an optical illumination system interposed between the light source and the reticle stage along the optical axis of the apparatus so as to direct light from the light source in a direction along the optical axis towards the reticle stage whereby a reticle mounted to the stage can be illuminated with light from the light source, a wafer stage, and an optical projection system interposed between the reticle stage and the wafer stage along the optical axis of the apparatus so as to project light from a reticle mounted to the reticle in a direction along the optical axis towards the wafer stage, and in which the optical illumination system includes a control mirror module having a control mirror substrate, and a plurality of unit control mirrors supported by the mirror substrate so as to divide the light received by the optical illumination system from the light source, and reflect the light to illuminate a number of domains. The unit control mirrors are adjustable to vary the intensity of the light among the domains.

### BRIEF DESCRIPTION OF THE DRAWINGS

These and other features and advantages of the inventive concept will be more apparent from the more detailed description of the preferred embodiments thereof, as illustrated in the accompanying drawings. In the drawings:

FIG. 1 is a schematic diagram of a reflective photolithography apparatus in accordance with the inventive concept;

FIG. 2A is a bottom view of a reflective reticle mounted in the reflective photolithography apparatus;

FIG. 2B is a top view of a wafer mounted on a wafer stage of the reflective photolithography apparatus and together with FIG. 2A illustrates a step and scan exposure process;

FIGS. 3A to 3F are each a perspective view of an example of a control mirror module of a reflective photolithography apparatus in accordance with the inventive concept;

FIGS. 4A and 4B are each a sectional view of an example of a unit control mirror of a control mirror module in accordance with the inventive concept;

FIGS. 5A to 5C are schematic diagrams of a unit control mirror of a control mirror module in accordance with the inventive concept illustrating the operation of the mirror;

FIGS. 6A and 6B are perspective views of examples of different joints used to support the unit control mirrors in accordance with embodiments of the inventive concept;

FIG. 7 is diagram perspective view of the control mirror module showing the unit control mirrors thereof tilted at various angles and in various directions;

FIG. 8A is a block diagram of a control device of the control mirror module in accordance with the inventive concept;

FIGS. 8B and 8C are each a circuit diagram of an example of components of the control device;

FIGS. 9A to 9C are each a conceptual diagram of an example of a way in which the intensity of EUV is controlled by the unit control mirrors of the control mirror module in accordance with the inventive concept;

FIGS. 10A to 10D are each a conceptual diagram of an example of a pattern of illumination that can be produced using the control mirror module in accordance with the inventive concept;

FIG. 11A is a diagram of a uniformity map of measured line widths of optical patterns of a reflective reticle in accordance the inventive concept;

FIG. 11B is a diagram of uniformity correction map for use in compensating for any non-uniformity of optical patterns of the reflective reticle;

FIG. 12A is a flowchart of an embodiment of an exposure process using the reflective photolithography apparatus in accordance with the inventive concept;

FIG. 12B is a flowchart of an inspection process for a wafer on which the exposure process has been performed in accordance with the inventive concept; and

FIG. 12C is a flowchart of a monitoring process for the exposure process in accordance with the inventive concept.

### DETAILED DESCRIPTION OF THE PREFERRED EMBODIMENTS

Various embodiments and examples of embodiments of the inventive concept will be described more fully hereinafter with reference to the accompanying drawings. Like numerals are used to designate like elements throughout the drawings.

Furthermore, spatially relative terms, such as “upper,” and “lower” and “horizontally” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use.

Other terminology used herein for the purpose of describing particular examples or embodiments of the inventive concept is to be taken in context. For example, the term “pattern” generally refers to a series of similar features that are repeated at certain intervals but may at times refer to more than one series of features. The terms “comprises” or “comprising” when used in this specification specifies the presence of stated features but does not preclude the presence or additional features.

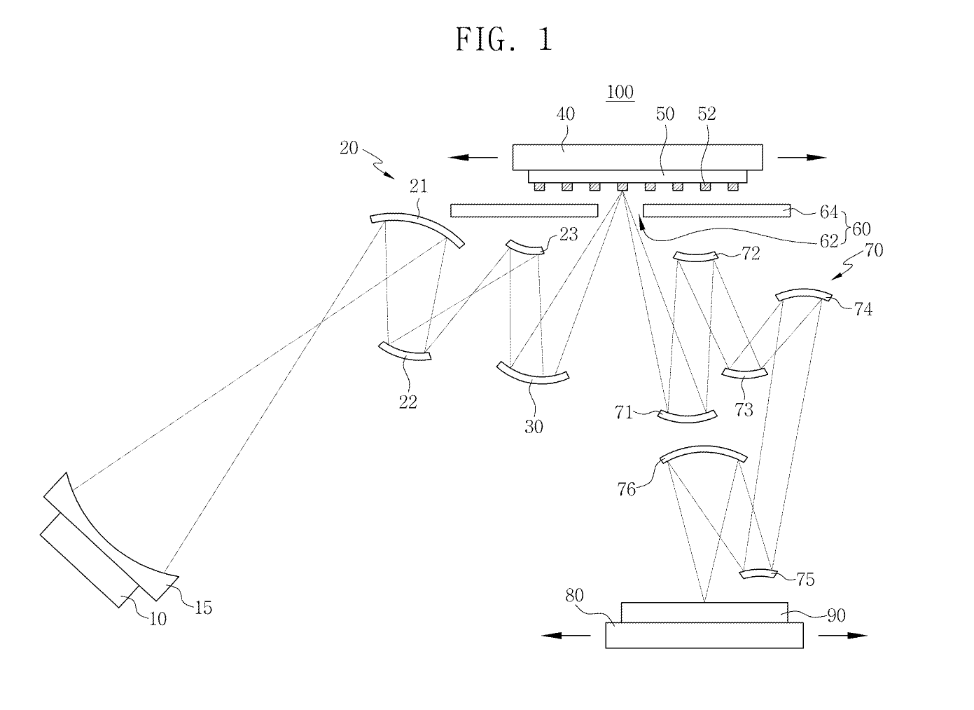

A reflective photolithography apparatus in accordance with the inventive concept will now be described in detail with reference to FIG. 1.

The reflective photolithography apparatus 100 includes a light source 10, an illumination mirror system 20, a reticle stage 40, a blinder 60, a projection mirror system 70, and a wafer stage 80.

The light source 10 may be of a type that generates extreme ultraviolet light (EUV). For example, the light source 10 generates light having a wavelength of about 13.5 nanometers using carbon plasma. A light collector 15 may be integrated with the light source 10. In this case, the collector 15 serves to collect the EUV generated by the light source 10 and transmit the EUV in a certain direction, i.e., along an optical axis of the apparatus 100, to the illumination mirror system 20. For example, the collector 15 may be a concave mirror such as a plano-concave mirror as shown in the figure.

In this embodiment, the illumination mirror system 20 includes a plurality of illumination mirrors, e.g., three illumination mirrors 21, 22, 23, and a control mirror module 30, that direct the EUV to the reticle stage 40. The illumination mirrors 21, 22, 23 themselves may be configured to condense the EUV in order to reduce loss in the apparatus, and such that the reflected light has a uniform intensity distribution. To these ends, each of the illumination mirrors 21, 22, 23 may be a concave or convex mirror arranged along the optical axis of the apparatus so as to change the direction along which the EUV propagates. In addition, the illumination mirror system 20 may shape the EUV, e.g., condense the EUV, into a beam having a square, circular, or bar-shaped cross section, and direct the beam of EUV to the reticle stage 40.

The control mirror module 30 controls the intensity distribution of the EUV, i.e., regulates the intensity of the EUV per unit area. For example, the control mirror module 30 may receive incident EUV having a uniform intensity distribution and reflect the incident EUV as a beam having a relatively high intensity across a first region thereof and a relatively low intensity across a second region thereof (as seen in a cross section of the beam of EUV). That is, the illumination mirror system 20 may output a beam of EUV whose intensity varies across respective areas thereof and direct such an altered beam of EUV to the reticle stage 40.

Still referring to FIG. 1, the control mirror module 30 is preferably disposed at the end of the illumination mirror system 20 with respect to the optical axis of the apparatus 100. Thus, the control mirror module 30 may receive the EUV from the illumination mirrors 21, 22, 23 and reflect the EUV directly to the reticle stage 40. The control mirror module 30 will be described in further detail below.

The reticle stage 40 can support a reflective reticle 50 at the bottom thereof. For example, the reticle stage 40 may include a plate, and an electrostatic chuck (ESC) to secure the reticle 50 to the bottom of the plate. The reticle stage 40 may also be moveable in the apparatus 100 back and forth along a horizontal axis as shown by the arrows.

The reflective reticle 50 has reflective optical patterns 52 that face downwardly when the reticle is mounted to the stage 40.

The blinder 60 is disposed below the reticle stage 40. The blinder 60 comprises a plate 64 having an exposure slit 62 extending therethrough. The EUV transmitted from the illumination mirror system 20 passes through the exposure slit 62 so as to irradiate the reflective reticle 50 on the reticle stage 40. The exposure slit 62 is elongated in a horizontal direction. In this embodiment, the cross-sectional area of the exposure slit 62 (in the plane of the plate 64) is bar-shaped and extremely narrow. Thus, the plate 64 intercepts one portion of the beam of EUV reflected by the illumination mirror system 20 whereas the exposure slit 62 allows another limited portion of the beam of EUV to pass through the blinder 60 to the reflective reticle 50. The EUV reflected from the reticle 50 passes back through the exposure slit 62 to the projection mirror system 70.

The projection mirror system 70 of this embodiment includes a plurality of projection mirrors 71-76 that can correct various aberrations. The mirrors 71-76 of the projection mirror system 70 receive the EUV which is reflected from the reflective reticle 50 through the exposure slit 62, and then direct the EUV along the optical axis of the apparatus 100 to a wafer stage 80 where the EUV irradiates a wafer 90 on the stage. More specifically, a photoresist layer of a certain thickness is formed on the wafer 90, and the focus of the projection mirror system 70 is located above the surface of the wafer 90 so that the EUV is focused to a location within the photoresist layer. In this way, the photoresist layer can be irradiated with EUV bearing a virtual image of the optical patterns 52 of the reflective reticle 50 and shaped by the exposure slit 62.

Still referring to FIG. 1, it should be noted that the optical axis along which the EUV propagates is shown conceptually for ease in understanding the general purposes behind the various components of the apparatus 100 described above.

The wafer stage 80 may be supported in the apparatus, like the reticle stage 40, so as to be movable back and forth along a horizontal axis, as shown by the arrows in FIG. 1. Also, the wafer stage 80 and the reticle stage 40 may be linked to move simultaneously in the same direction but at a different rates, the ratio of which will be referred to hereinafter as a “movement ratio”. Furthermore, the apparatus 100 may be configured so that the movement ratio may be adjusted. For example, when the movement ratio is set to 10:1, if the reticle stage 40 is moved 10 μm left or right, the wafer stage 80 is simultaneously moved 1 μm in the same direction over the same period of time. Or, when the movement ratio is set to 5:1, if the reticle stage 40 is moved 10 μm to the left or right, the wafer stage 80 is moved 2 μm in the same direction over the same period of time.

In an example of this embodiment, the wafer stage 80 is supported so as to be moveable along horizontal X- and Y-axes that orthogonal to each other. For example, the X-axis extends along the same direction of movement as the reticle stage 40 and corresponds to a scan direction and the Y-axis corresponds to a step direction. Accordingly, the apparatus 100 can execute a step-and-scan process which will be described in more detail below.

The wafer stage 80 may also be supported in the apparatus 100 so as to be vertically moveable, in whole or in part, such that the focus of the apparatus can be adjusted and maintained at a certain level relative to a wafer supported on the wafer stage 80.

An additional optical component or components, e.g., a blinder, beam shaper, and/or aperture, etc., may be provided above the wafer stage 80, i.e., between the wafer stage 80 and the projection mirror system 70 with respect to the optical axis of the apparatus 100.

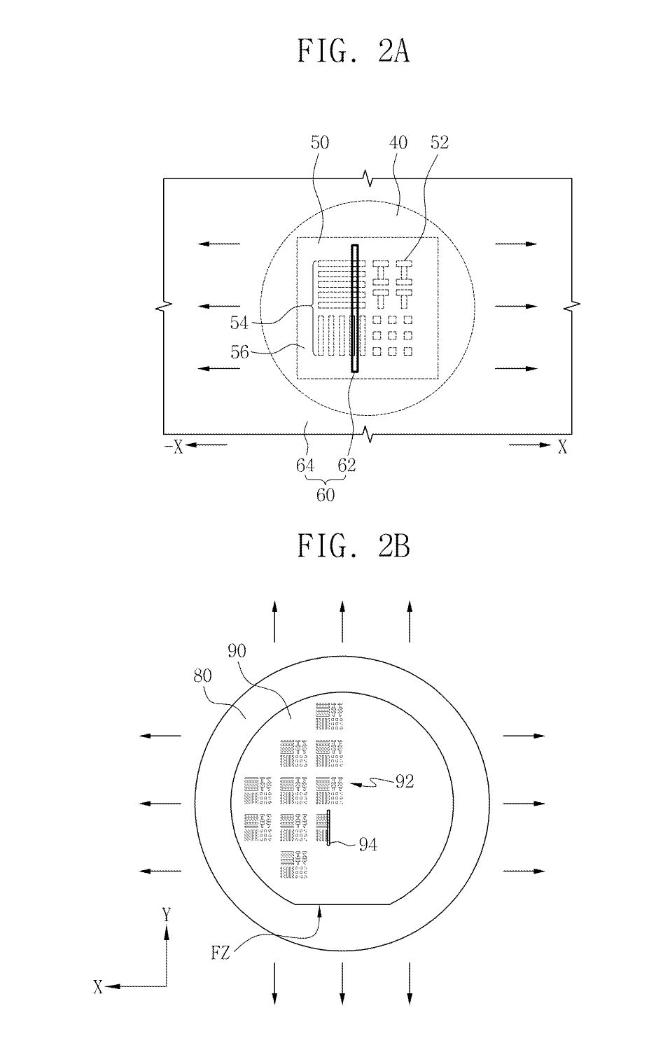

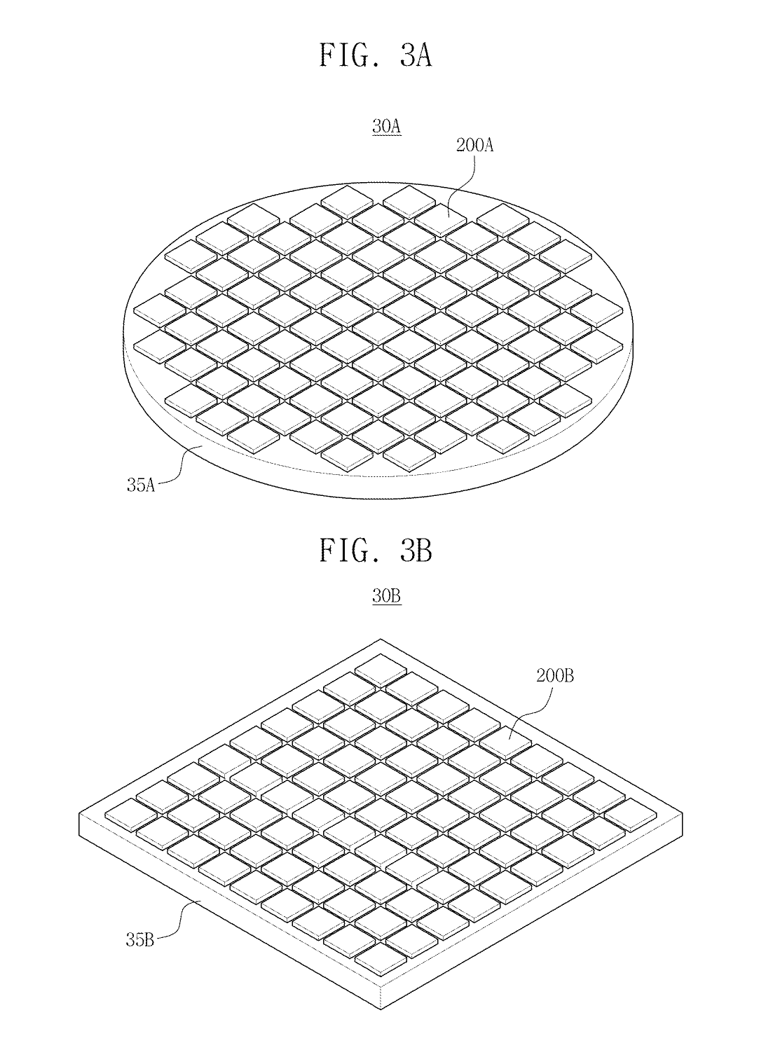

An example of an exposure process using the reflective photolithography apparatus 100 in accordance with the inventive concept will now be described with reference to FIGS. 2A and 2B. FIG. 2A is a bottom view of the reflective reticle 50 and FIG. 2B is a top view of the wafer 90.

Referring to FIG. 2A, the exposure process comprises moving the reflective reticle 50 relative to the exposure slit 62. More specifically, in a process employing the above-described embodiment of a reflective photolithography apparatus, the reticle stage 40 is moved along the X-axis, that is, in a direction perpendicular to the lengthwise direction of the elongated exposure slit 62. Thus, the reflective reticle 50 is moved horizontally by the reticle stage 40 while the aperture 60 remains fixed. As a result, the exposure slit 62 is, in effect, scanned across the surface of the reflective reticle 50.

The reflective reticle 50 has a pattern area 54 and a peripheral area 56 in this example. The pattern area 54 is the area occupied by the optical patterns 52 of the reticle 50 and the peripheral area 56 surrounds the pattern area 54. The exposure slit 62 scans only the pattern area 54 of the reflective reticle 50 in this example.

Referring to FIG. 2B, the EUV from the light source 10 is directed through the exposure slit 62 of the blinder 60 by the illumination mirror system 20. As a result, the surface of the reflective reticle 50 is scanned with the EUV, and the EUV reflected from the reflective reticle 50 through the exposure slit 62 contains a virtual aerial image of the optical patterns 52. The aerial image of the optical patterns 52 is projected by the projection mirror system 70 onto the wafer 90 to form optical virtual image 92 on the (photoresist layer on the) wafer 90.

Also, in this example, the projection mirror system 70 projects the EUV containing the aerial image of the optical patterns 52 to a fixed location above the wafer stage 80, while the wafer stage 80 is moved horizontally at a rate that is a fraction of that of the reticle stage 64 (refer to the description above pertaining to the “movement ratio”). At this time, the wafer 90 is fixed on the stage 80 with its flat zone (FZ) facing in a given direction (the direction of the Y-axis in this example).

After the reticle 50 has been scanned once and an aerial image of the optical patterns 52 of the reticle 50 has been transferred to a region of the wafer 90, the wafer stage 80 is moved to bring another region of the wafer 90 to the location at which the projection mirror system 70 focuses the EUV in the apparatus. Then the reticle 50 is scanned again with the EUV, and an aerial image of the optical patterns 52 of the reticle is transferred to that region of the wafer 90. FIG. 2B shows an example in which the aerial image is being transferred for a tenth time to the wafer 90 in this way. Typically, these regions are demarcated by scribe lanes. In the process described above, a photoresist layer on the wafer 90 is irradiated with the EUV and hence, exposed to the aerial images. Therefore, such scribe lanes and other features at the upper surface of the wafer 90 can not be seen in the plan view of FIG. 2B. However, the virtual images of the patterns transferred to the photoresist are illustrated for ease in understanding.

Examples of the control mirror module 30 will now be described in more detail.

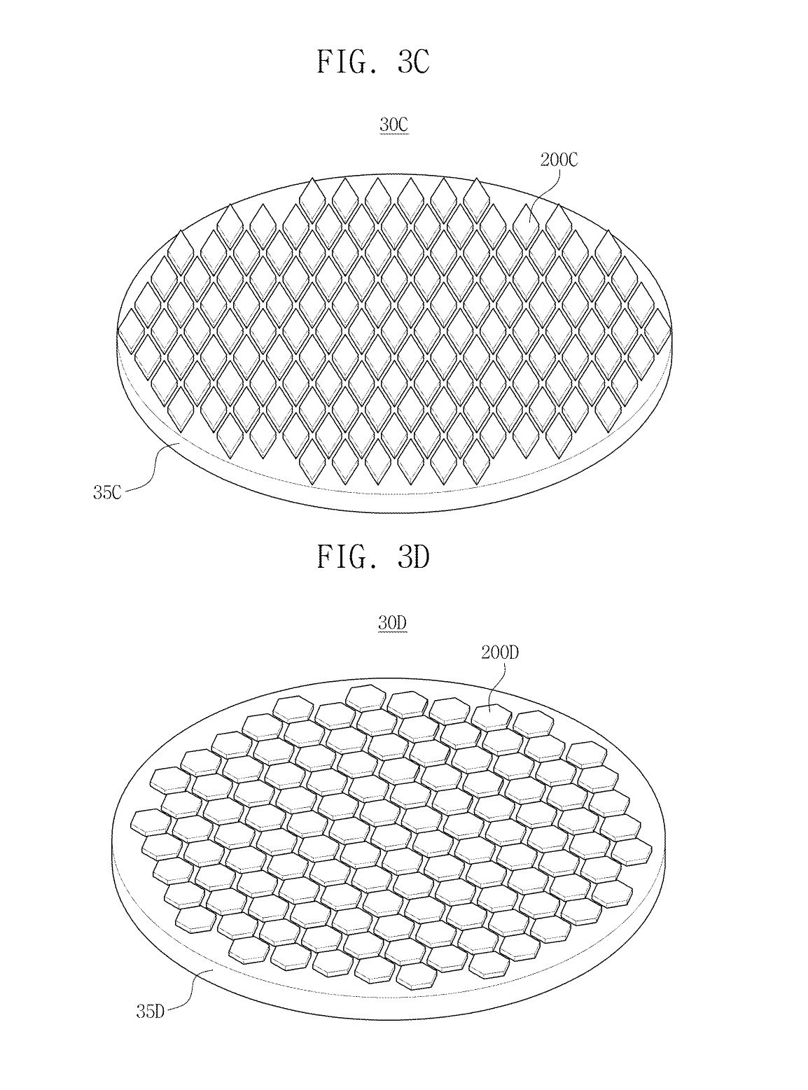

Referring to FIGS. 3A to 3F, the control mirror module 30A-30F includes a mirror substrate 35A-35F, and a plurality of unit control mirrors 200A-200F arranged in a cellular array or matrix on the mirror substrate 35A-35F.

The mirror substrate 35A-35F may be ceramic, glass, or metal substrates, or may be constituted by a printed circuit board (PCB). The mirror substrate 35A-35F may be circular or polygonal. Also, the mirror substrate 35A-35F may be planar (as illustrated) or may be concave or convex. Examples of control mirror modules having circular substrates are shown in FIGS. 3A and 3C to 3F, whereas an example of a control mirror module having a polygonal substrate (in this case a rectangular substrate) is shown in FIG. 3B.

Preferably, the greatest dimension of the mirror substrate 35A-35F is on the order of tens of centimeters. For example, the diameter of the mirror substrate 35A, 35C-35F is preferably on the order of tens of centimeters, and more preferably in a range of 30 to 60 centimeters. When the mirror substrate 35B is polygonal, the length of its longest side or of its diagonal is preferably on the order of tens of centimeters, and more preferably in a range of 30 to 60 centimeters.

The size (longest dimension) of each of the unit control mirrors 200A-200F is on the order of tens to hundreds of micrometers. The shape of each of the unit control mirrors 200A-200F may be polygonal such as rectangular, rhombic, or hexagonal, or circular or oval or elliptical as shown in FIGS. 3A-3F. In some cases, such as when the unit control mirrors are elliptical as shown in FIG. 3F, the control mirrors 200F may be arranged in rows, with the mirrors 200F in each row being offset relative to the mirrors 200F in each row adjacent thereto.

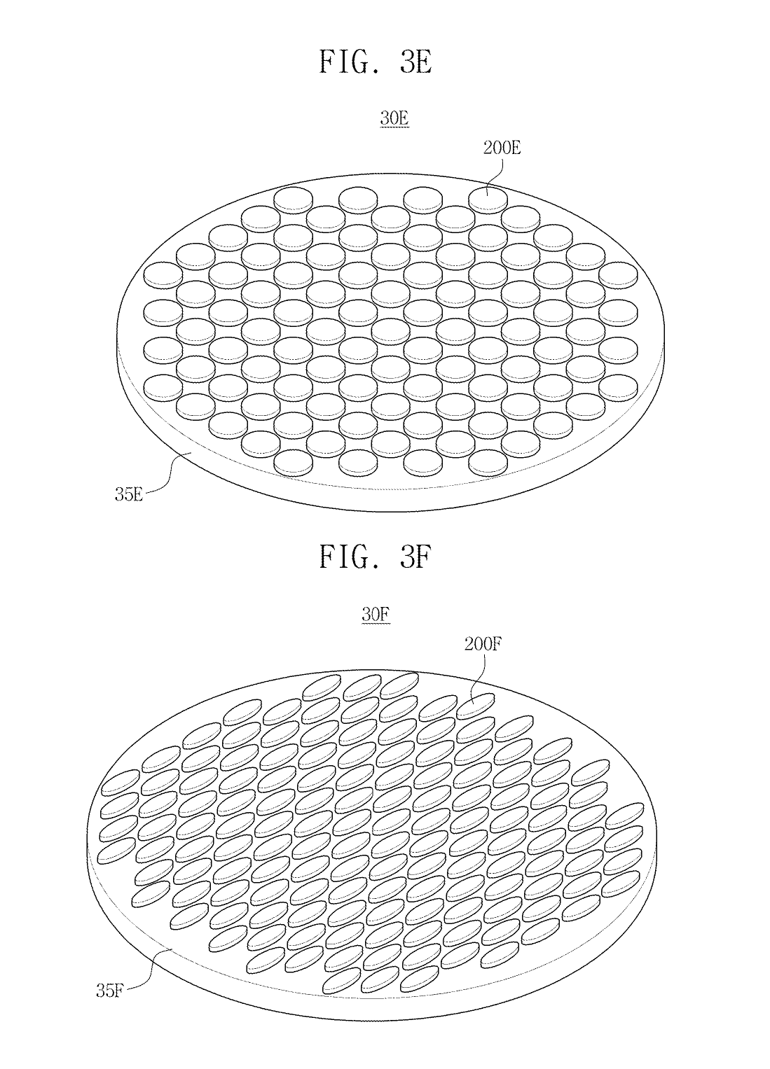

Examples of structures of the unit control mirrors 200 in accordance with the inventive concept are shown in FIGS. 4A and 4B.

In the example shown in FIG. 4A, each unit control mirror 200 includes a unit mirror substrate 210 and a reflective stack 220 disposed on the unit mirror substrate 210. The unit mirror substrate 210 may comprise any of a variety of magnetic substances or metals such as chromium, nickel, cobalt, molybdenum, aluminum, or iron. The reflective stack 220 is made up of pairs of unit reflective layers 222, i.e., a first unit reflective layer 224 and a second unit reflective layer 226. As one example, the first unit reflective layer 224 is a layer of silicon having a thickness of approximately 4.1 nm and the second unit reflective layer 226 is a layer of molybdenum having a thickness of approximately 2.7 nm. The reflective stack 220 may include approximately forty pairs of unit reflective layers 222. The reflective layer 220 may also include a capping layer 228 (a mono-layer or a laminate) disposed on the pairs of unit reflective layers 222. The capping layer 228 may comprise a layer of silicon or silicon oxide. In the case in which capping layer 228 comprises a layer of silicon oxide, the thickness of the silicon oxide layer is approximately 5 to 13 nm.

In the example shown in FIG. 4B, the unit mirror substrate 210 includes a silicon layer 214 and a metal layer 212 disposed on the bottom surface of the silicon layer 214. The metal layer 212 is magnetic.

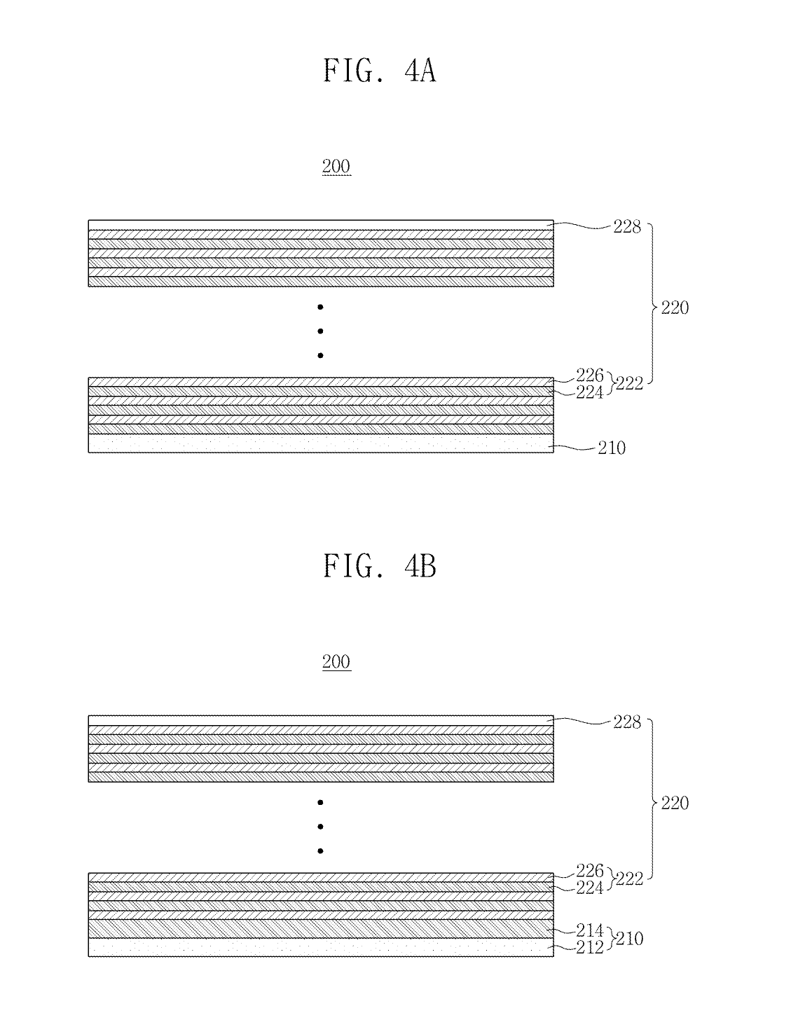

Referring to FIGS. 5A to 5C, the control mirror module 30 also includes supports 230 disposed on the mirror substrate 35 and supporting the unit control mirrors 200. In FIGS. 5A-5C, for the same of simplicity only one such support 230 and unit control mirror 200 is shown, and the components of the control mirror module 30 including the mirror substrate 35 are not shown to scale.

The support 230 includes a joint 240, at an upper portion thereof, that allows the unit control mirrors 200 to rotate or tilt relative to the mirror substrate 35. The control mirror module 30 also has a plurality of electromagnets 250 integrated with the mirror substrate 35. The electromagnets 250 are disposed at or near (adjacent) an upper surface of the mirror substrate 35 as juxtaposed with the unit mirror substrates 210 of the unit control mirrors 200. More specifically, at least two respective electromagnets 250 are juxtaposed with each unit mirror substrate 210. The electromagnets 250 are operable form a magnetic field that attracts or repels the unit mirror substrate 210. Thus, the unit control mirrors 200 can be tilted at various angles by the magnetic field of the electromagnets 250. In this respect, the control mirror module 30 also has control circuits 260 integrated with the mirror substrate 35, in this example, to control the magnetic field of the electromagnets 250. The control circuits 260 may include a MOS transistor 270. Each of the control circuits may be operated independently. As an example, FIGS. 5B and 5C show the tilting of a unit control mirror 200 by two of the control circuits 260.

The above-described components of the control mirror module 30 may be configured such that each unit control mirror 200 may be tilted to a maximum angle of 30 degrees from its home position at which it is level with respect to the mirror substrate 35. It has been determined experimentally that the intensity of the EUV can be controlled sufficiently if the unit control mirrors 200 are tilted only by approximately 10 degrees.

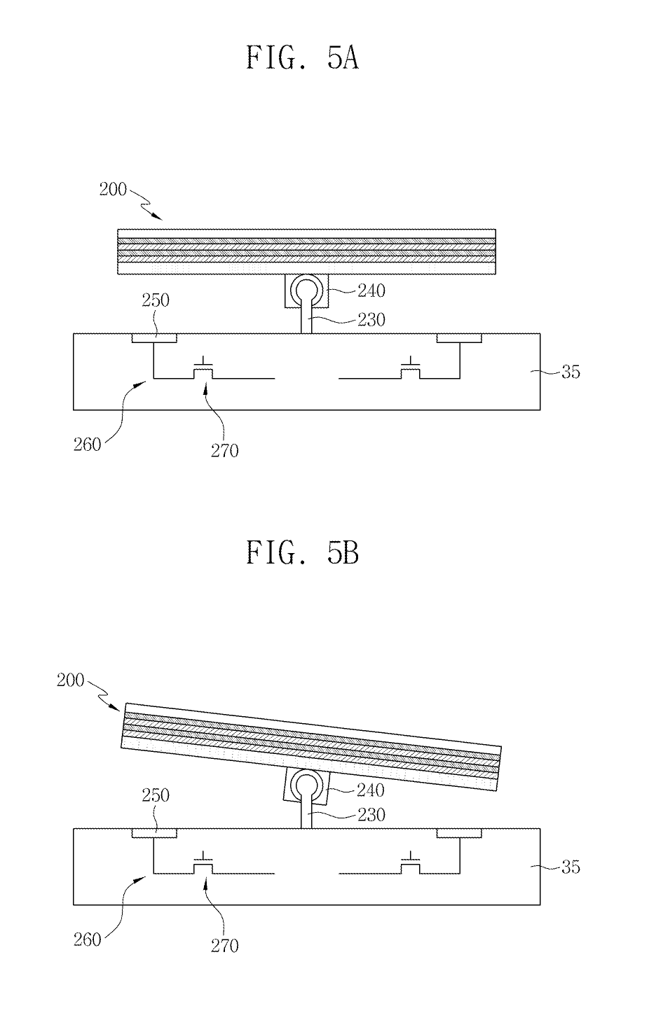

FIGS. 6A and 6B show examples of the joints 240.

Referring to FIG. 6A, the joint comprises a hinge 241. For example, the hinge 241 includes a pivot housing 242 mounted to the bottom of the unit mirror substrate 210 and a pivot shaft 243 received in the pivot housing 242. The pivot housing 242 and hence, the unit mirror 200, can pivot about the longitudinal axis of the pivot shaft 243.

Referring to FIG. 6B, the joint comprises a ball joint 246. For example, the ball joint 246 include a socket 247 mounted to the bottom of the unit mirror substrate 210 and a ball 248 received in the socket 247. The socket 247 and hence, the unit mirror 200, can tilt in various directions about the ball 248.

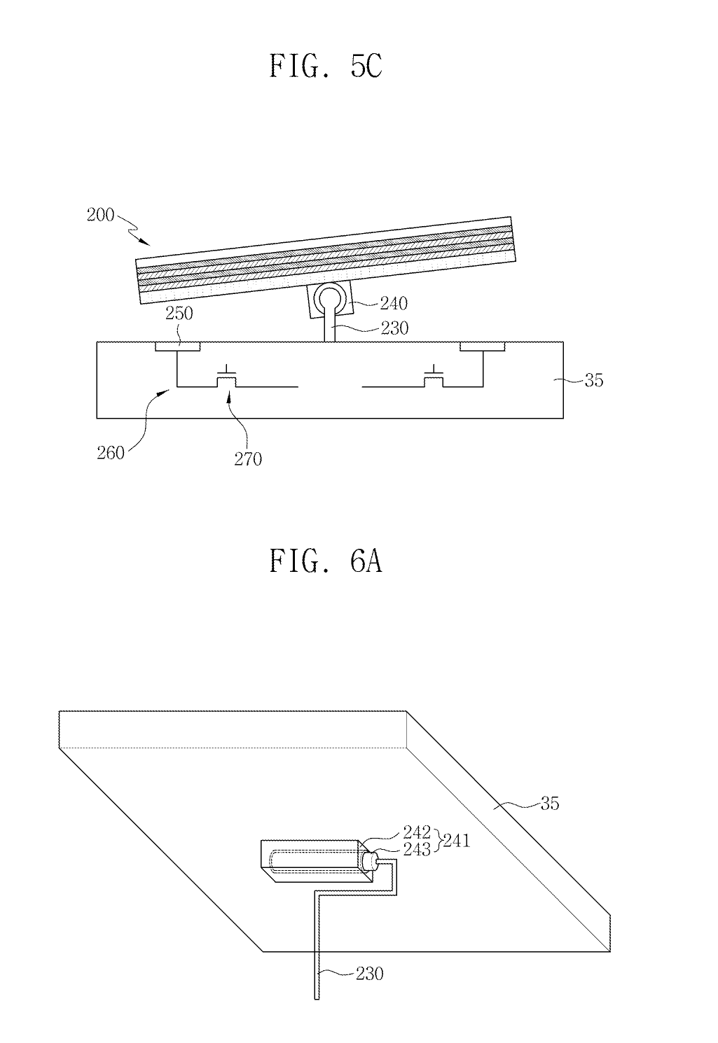

FIG. 7 shows an example of the control mirror module 30 in which the unit control mirrors 200 thereof are tilted at various angles. That is FIG. 7, shows that the unit control mirrors 200 may be inclined independently in various directions and at various angles.

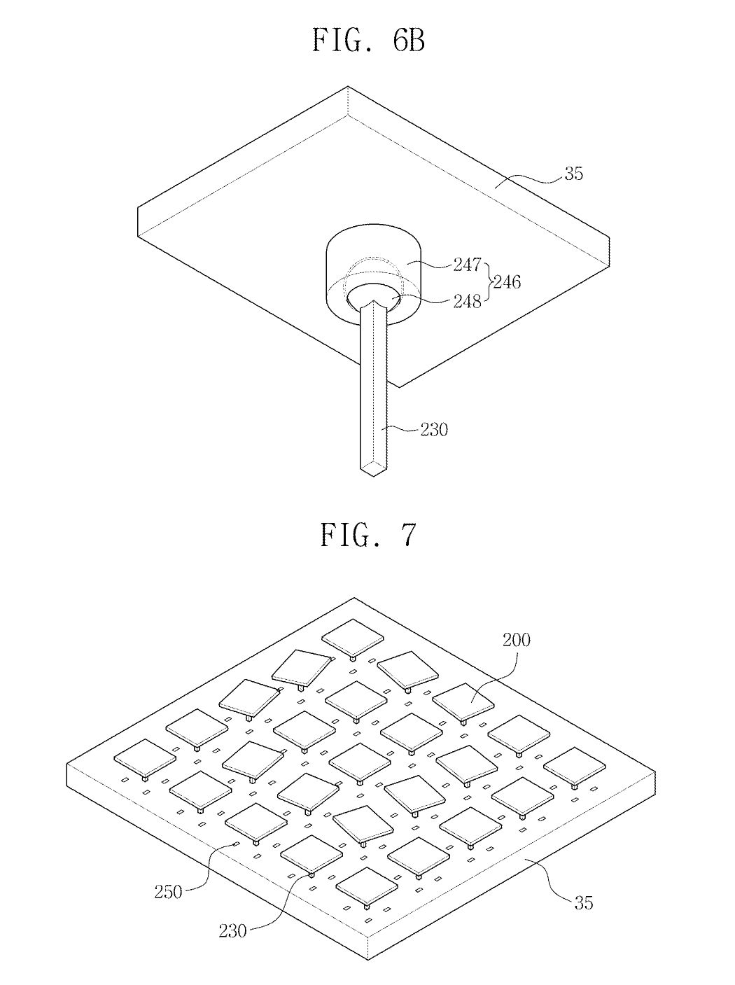

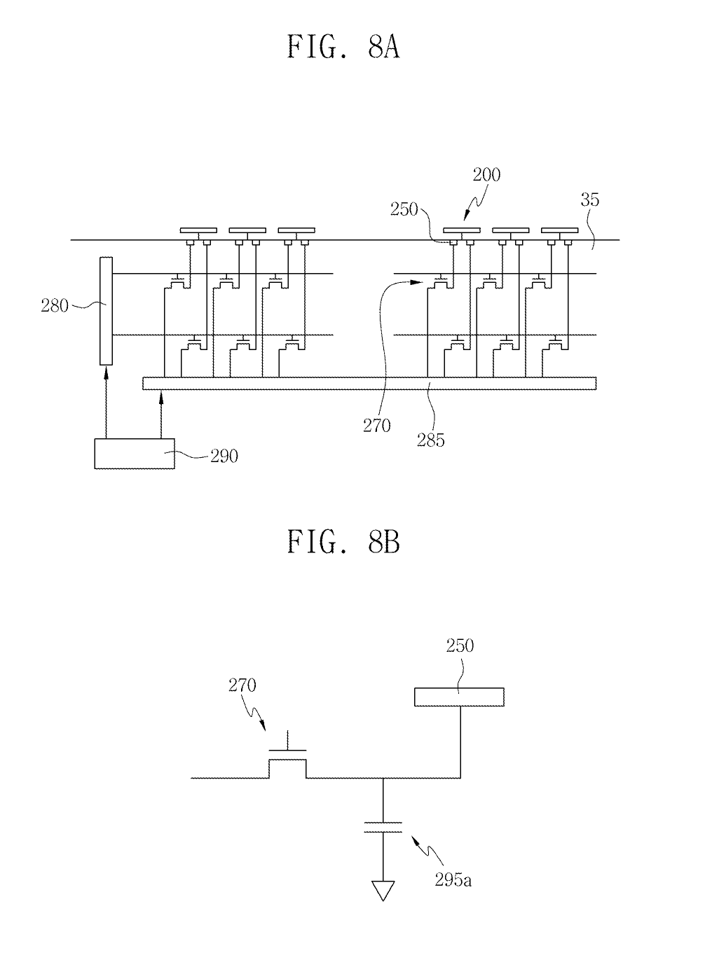

Examples of the control circuits of the control mirror module 30 in accordance with the inventive concept will now be described in detail with reference to FIGS. 8A to 8C. Referring to FIG. 8A, each control circuit includes a MOS transistor 270 which has a source electrode connected to a bit line driver 285, a drain electrode connected to an electromagnet 250, and a gate electrode connected to a word line driver 280. The word line driver 280 and the bit line driver 285 are connected to a controller 290. Thus, in this example, when the MOS transistor 270 is turned on by the word line driver 280, the current supplied from the bit line driver 285 is transferred to the electromagnet 250 such that the electromagnet 250 produces a magnetic field.

Referring to FIGS. 8B to 8C, each control circuit may also include a voltage regulator, e.g., a coupling capacitor 295a or diode 295b, connected to the drain electrode. The voltage regulator 295a and 295b ensures that the electromagnet 250 produces a uniform discrete magnetic field.

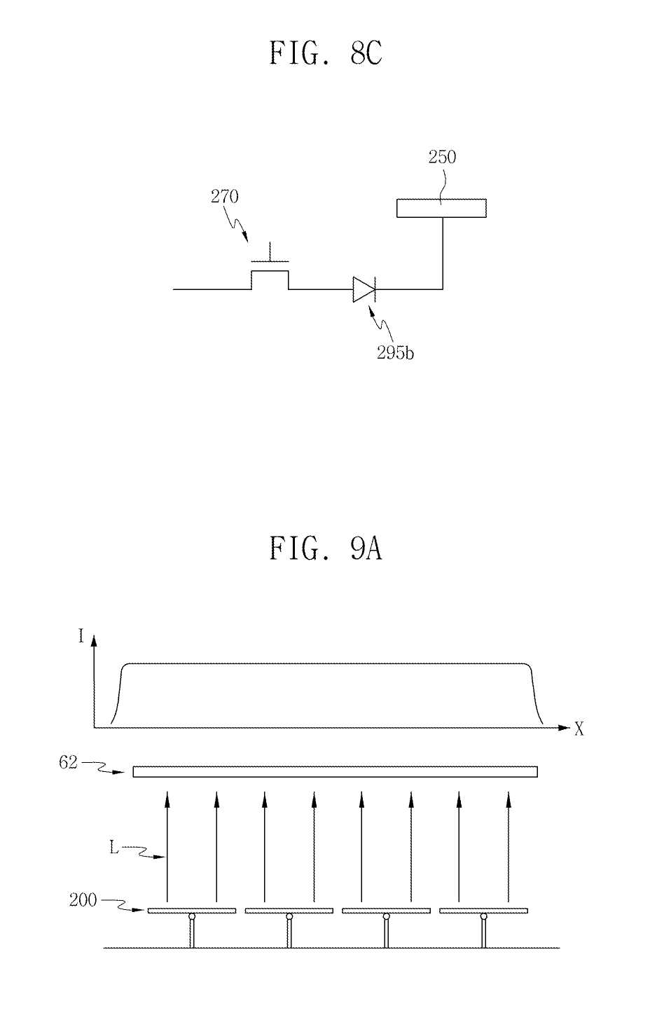

FIGS. 9A to 9C conceptually illustrate ways in which the intensity of EUV illuminating the reticle can be controlled by the reflective photolithography apparatus in accordance with the inventive concept.

Referring to FIG. 9A, the unit control mirrors 200 are oriented horizontally (or with all of their reflective surfaces being disposed in the same plane). As a result, the intensity of the EUV is uniform across the exposure slit 62.

Referring to FIG. 9B, some of the unit control mirrors 200 are tilted such that the intensity distribution of the EUV across the exposure slit 62 is biased or has gray levels. For instance, as shown in this example, central ones of the unit control mirrors 200 are tilted to toward the outer periphery of the mirror substrate 35 of the control mirror module 30. As a result, the intensity of the EUV becomes lower at the center of the exposure slit 62, and higher at the ends of the exposure slit 62.

Referring to FIG. 9C, a set of the unit control mirrors 200 are tilted in the same direction toward one side of the mirror substrate 35 of the control mirror module 30. As a result, the intensity of the EUV becomes lowest at one end of the exposure slit 62k, lower at the center of the exposure slit 62, and highest at the other end of the exposure slit 62.

As can be fully appreciated from FIGS. 9A to 9C, the control mirror module 30 in accordance with the inventive concept can adjust the intensity of the EUV in a plurality of areas, e.g. cells, in various ways to obtain virtually any desired intensity distribution (profile) across the reflective reticle and wafer.

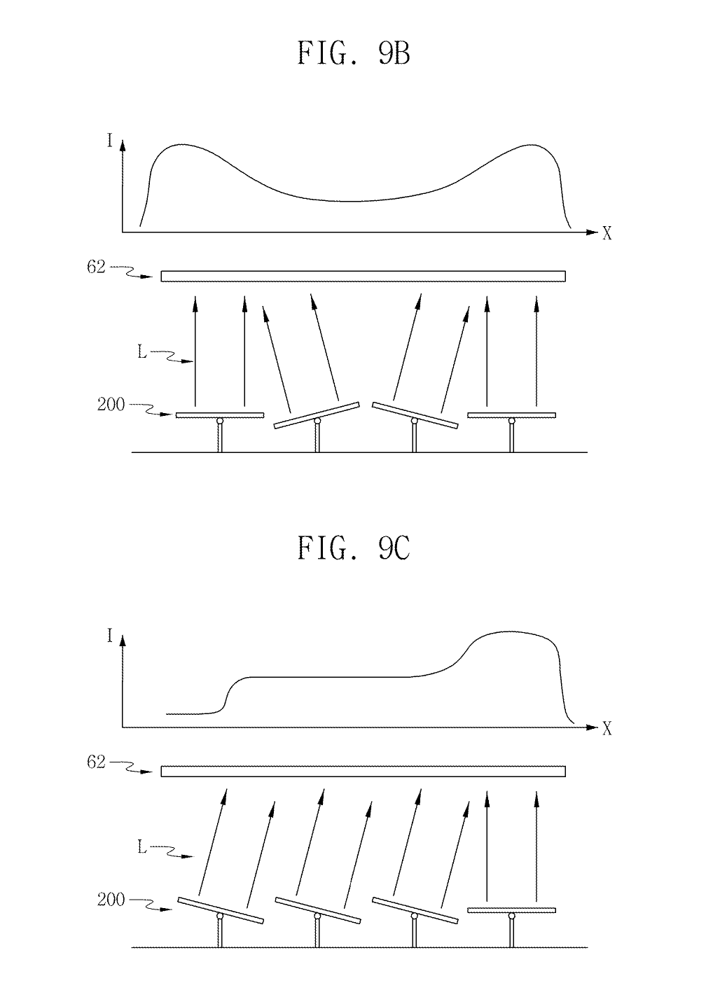

FIGS. 10A to 10D illustrate ways in which the intensity distribution of the EUV can be controlled by reflecting the EUV onto domains (areas in space) using the unit control mirrors. For example, these domains coincide with the blinder 60 in this embodiment.

Referring to FIG. 10A, areas IR1 of the blinder 60 illuminated with EUV by the unit control mirrors 200, respectively, overlap only other areas IR1 along their peripheries (or not at all). For simplicity, the shapes of areas IR1 are illustrated as having rounded corners. Therefore, intensity distribution of the EUV reflected by the control mirror module 30 will be entirely uniform.

Referring to FIG. 10B, areas IR2 on the blinder 60 illuminated with EUV by the unit control mirrors 200 overlap to a larger extent than the areas IR1 in the example shown in and described above with reference to FIG. 10A. For example, the areas IR2 overlap substantially at the center of the blinder 60. Therefore, intensity distribution of the EUV reflected by the control mirror module 30 will be higher at the center than at the periphery of the blinder 60.

Referring to FIG. 10C, areas IR3 on the blinder 60 illuminated with the EUV by the unit control mirrors 200 overlap asymmetrically. For example, an overlapping area OL1 between first and second columns of the EUV is larger than an overlapping area OL2 between the second column and a third column of the EUV (OL1>OL2). In addition, an overlapping area OL3 between the third column of the EUV and a fourth column of the EUV is larger than the overlapping area OL2 (OL3<OL2). Also, the overlapping area OL3 may be larger than the overlapping area OL1.

Referring to FIG. 10D, each area IR4 of the blinder 60 illuminated with EUV by a unit control mirror 200 overlaps several of the other areas IR4. This pattern of illumination can be achieved when, for example, the unit control mirrors 200 are convex mirrors or when the unit control mirrors 200 are planar mirrors and the mirror substrate 35 is concave.

Thus, it can be appreciated from FIGS. 10A to 10D that various patterns of illumination of the EUV may be provided by the control mirror module according to the inventive concept.

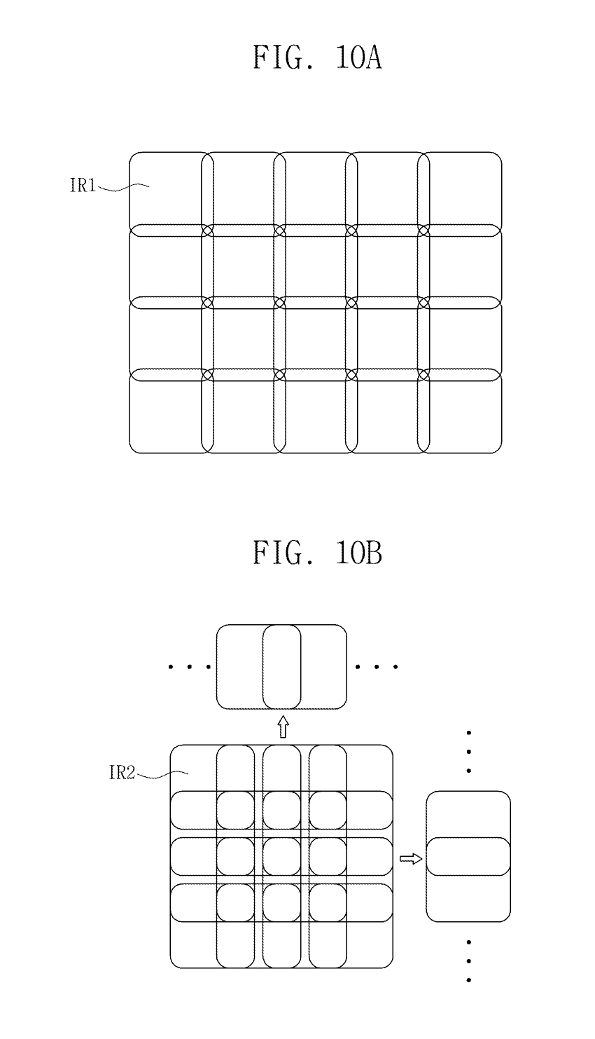

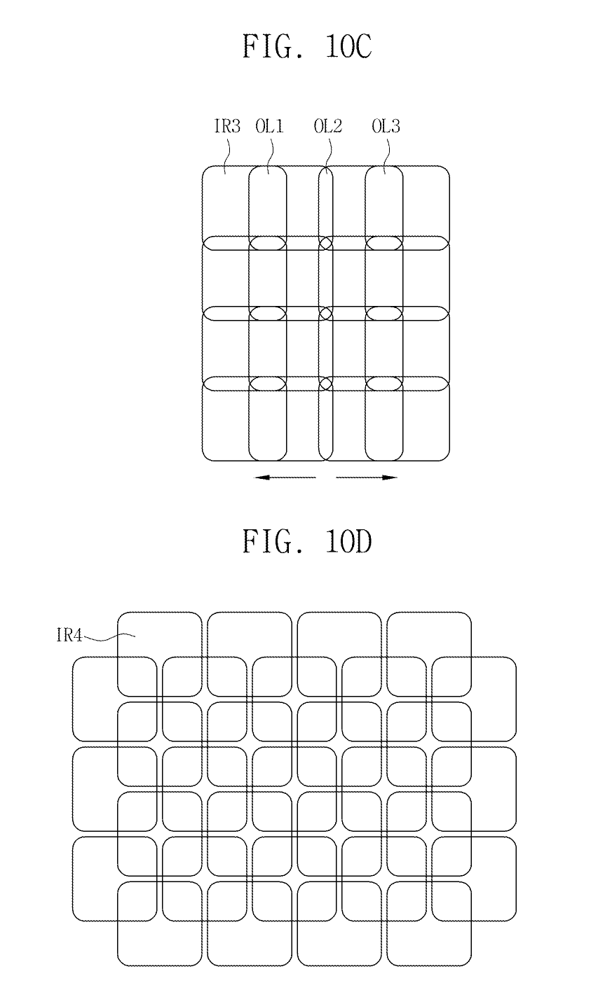

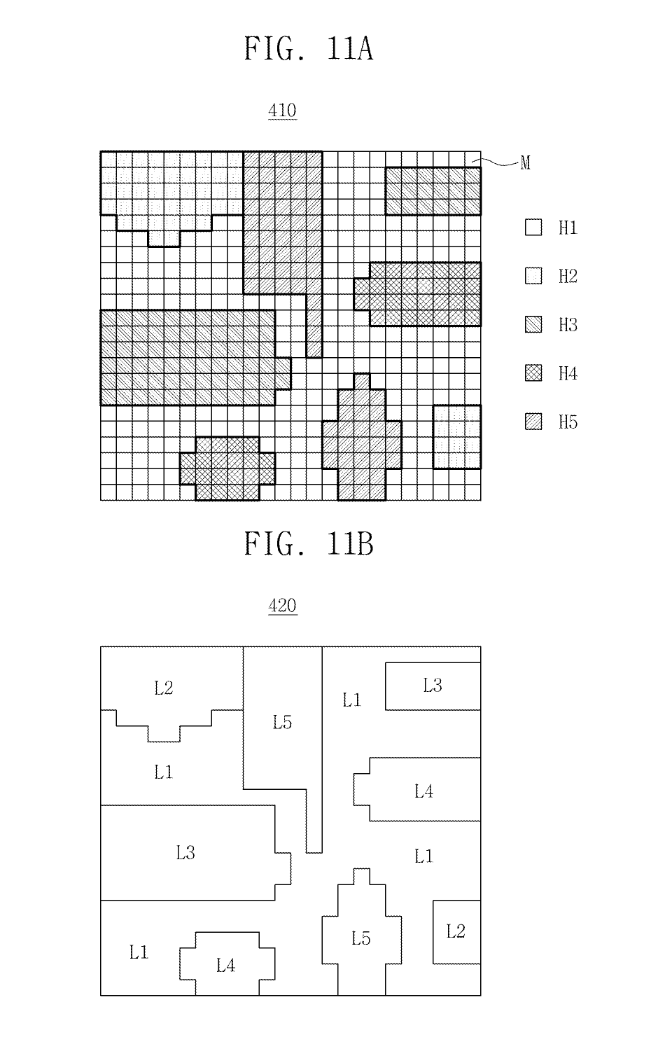

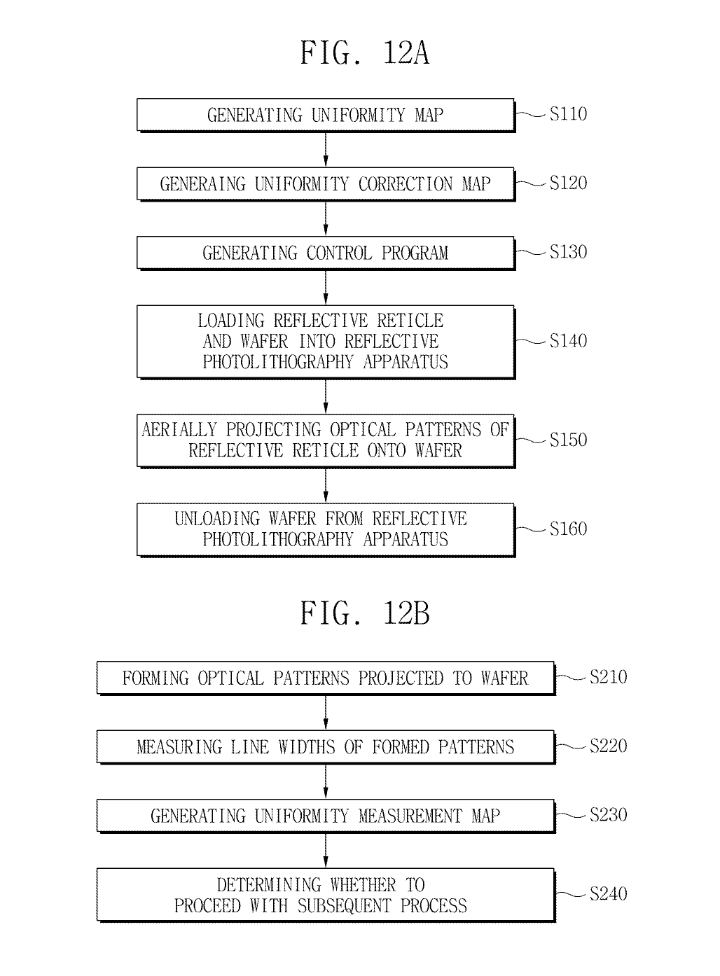

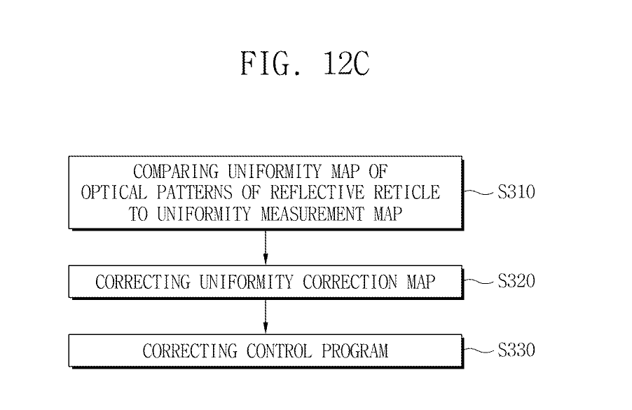

An example of an exposure process using the reflective photolithography apparatus 100 according to the inventive concept will now be described with reference to FIG. 11A-12C. In this example, the optical patterns 52 of the reflective reticle 50 are line and space patterns and the uniformity of the optical patterns 52 is a measure of the uniformity of the line widths of the line and space patterns.

FIG. 11A is a uniformity map 410 of measured line widths of the optical patterns 52 of the reflective reticle 50, and FIG. 11B is a uniformity correction map 420 for use in correcting the uniformity of the optical patterns 52 of the reflective reticle 50.

Referring to FIG. 11A, the uniformity map 410 of the optical patterns 52 is a grid showing the uniformity of the line widths of the optical patterns 52 according to an average value of the line widths in areas of the reticle 50. The areas are demarcated according to the level of the average value of the line widths. For example, the uniformity map 410 may include an area H1 in which the average value of the line widths of the optical patterns 52 is lowest and areas H2 to H5 in which the average values of the line widths of the optical patterns 52 progressively increase. Although in this example the uniformity map 410 has classifies the average values of the line widths into five different levels, the map 410 may classify the average values of the line widths into more or fewer levels as needed.

Referring to FIG. 11B, the uniformity correction map 420 has an area L1 in which the intensity of the EUV should be increased and areas L2 to L5 in which the intensity of EUV should be progressively decreased, to compensate for the differences in uniformity of the optical patterns 52 of the reflective reticle 50 shown in the map 410 in FIG. 11A. More specifically, in this example, because the average value of the line widths of the optical patterns 52 is relatively high in area L1, the control mirror module 30 will be controlled to decrease the intensity of the EUV illuminating an area of the reticle corresponding to area L1 on the map 420. Conversely, because the average value of the line widths of the optical patterns 52 is relatively low in area L5, the control mirror module 30 will be controlled to increase the intensity of the EUV illuminating that area of the reticle corresponding to area L5 on the map 420.

Referring to FIG. 12A, the exposure process in accordance with the inventive concept includes generating a uniformity map 410 of the optical patterns 52 of the reflective reticle 50 (S110). The generation of the uniformity map 410 may include measuring the line widths of the optical patterns 52 on the reflective reticle using, for example, a critical dimension-scanning electron microscope (CD-SEM) or aerial image measurement system (AIMS), calculating the average values, and classifying and displaying the average values in each of the unit areas of the grid. The unit areas may be of various sizes. For example, they may be several micrometers to hundreds of micrometers square. Basically, the size of the unit areas will depend on the tolerance of the optical patterns 52.

Next, a uniformity correction map 420 is produced based on the uniformity map 410 (S120). The uniformity correction map 420 may display several demarcated areas corresponding to areas of the reticle 50 at which the intensity of the EUV should be raised and lowered.

Next, a control program for controlling the unit control mirrors 200 of the control mirror module 30 is generated based on the uniformity correction map 420 (S130). The control program includes commands controlling the unit control mirrors 200 such that the control mirror module 30 reflect a greater amount of the EUV to the areas at which the intensity of the EUV should be higher and reflect less of the EUV to the areas at which the intensity of the EUV should be lower.

Next, the reflective reticle 50 and the wafer 90 are loaded into the reflective photolithography apparatus 100 (S140). For example, the reflective reticle 50 is mounted on the reticle stage 40 such that the surface on which the optical patterns 52 are formed faces down, and the wafer 90 is mounted on the wafer stage 80.

Next, an aerial image of the optical patterns 52 of the reflective reticle 50 is projected onto the wafer 90 (S150). In particular, a photoresist layer formed on the wafer 90 is exposed to the aerial image of the optical patterns 52 of the reflective reticle 50 while the unit control mirrors 200 of the control mirror module 30 are positioned according to the control program. The exposure process may be executed in a step-and-scan manner. That is, as was described with reference to FIGS. 2A and 2B, the wafer stage 80 on which the wafer 90 is mounted is moved in a step-wise manner to bring respective semiconductor chips on the wafer 90 into alignment with (the optical axis of) the apparatus, and an aerial image of the optical patterns 52 is projected onto each of the chips by a scanning method in which the reticle stage 40 and the wafer stage 80 are moved horizontally at different rates.

Next, the wafer 90 is removed from the reflective photolithography apparatus 100 (S160). Then the wafer 90 is inspected.

Referring to FIG. 12B, the inspection process includes forming patterns on the wafer 90 corresponding to the optical patterns 52 (S210). Specifically, the photoresist layer exposed to the aerial image of the optical patterns 52 is developed to form a photoresist pattern. In addition, material (a target layer) under the photoresist pattern is itself patterned (etched) using the photoresist pattern as a mask. Then, the photoresist pattern may be removed.

In addition, the line widths of the patterns formed on the wafer 90 are measured (S220). This process may include measuring the line widths of the photoresist patterns and the line widths of the patterned target layer, and generating data representative of the measured line widths of the photoresist patterns and/or target layer patterns formed on the wafer 90.

Next, a uniformity measurement map based on the data of the measured line widths is produced (S230). The uniformity measurement map maps the uniformity of the photoresist patterns and/or target layer patterns.

Next, determining determination is made as to whether to proceed with the process (S240). Such a determination may be based on whether the uniformity of the measured photoresist patterns or target layer patterns meets a certain tolerance, i.e., is within a range of predetermined values.

The exposure process may also include a self-monitoring process in accordance with the inventive concept.

Referring to FIG. 12C, the monitoring process may include comparing the uniformity map 410 of the optical patterns 52 of the reflective reticle 50 to the uniformity measurement map produced after the target layer is patterned (S310). Data representative of the comparison of the uniformity maps is generated. The comparative data may be data of domain-specific differences between the uniformity map 410 and the uniformity measurement map.

Next, the uniformity correction map 420 is corrected based on the comparative data (S320). Therefore, the correction map 420 may be corrected based on domain-specific differences between the uniformity map 410 and the uniformity measurement map.

Next, the control program is corrected (overwritten) based on the corrected uniformity correction map 420 (S330).

As a result, the next exposure process is carried out according to the corrected control program.

As described above, according to an aspect of the inventive concept, the reflective photolithography apparatus can control the intensity distribution of the exposure light, and compensate for any non-uniformity in an optical pattern(s) of a reflective reticle in real time.

In addition, according to an aspect of the inventive concept, the reflective photolithography apparatus according to the inventive concept can perform exposure processes without the need to reproduce or correct a reflective reticle. Therefore, a reflective photolithography apparatus according to the inventive concept can help to reduce manufacturing costs and keep production time to a minimum.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A reflective photolithography apparatus, comprising:
a light source;
an illumination mirror system having a plurality of illumination mirrors and a control mirror module, wherein the control mirror module includes a plurality of unit control mirrors having reflective surfaces, respectively, that are each adjustable;
a reticle stage;
a projection mirror system including a projection mirror; and
a wafer stage.

2. The reflective photolithography apparatus according to claim 1, wherein the control mirror module is disposed between the illumination mirrors and the reticle stage along an optical axis of the apparatus.

3. The reflective photolithography apparatus according to claim 1, wherein the control mirror module includes a mirror substrate, and the unit control mirrors are disposed in an array on the mirror substrate.

4. The reflective photolithography apparatus according to claim 3, wherein each of the unit control mirrors is supported on the mirror substrate so as to be tiltable relative to a home position at which the reflective surface thereof is level relative to the mirror substrate, and is confined to be tiltable over a maximum angle of less than 30 degrees relative to its home position.

5. The reflective photolithography apparatus according to claim 3, wherein each of the unit control mirrors includes a unit mirror substrate and reflective layers stacked on the unit mirror substrate.

6. The reflective photolithography apparatus according to claim 5, wherein the unit mirror substrate includes a metal layer and a silicon layer.

7. The reflective photolithography apparatus according to claim 6, wherein the metal layer is magnetic.

8. The reflective photolithography apparatus according to claim 5, wherein the control mirror module includes supports that connect the unit control mirrors to the mirror substrate, the supports comprising joints that allow the unit control mirrors to tilt.

9. The reflective photolithography apparatus according to claim 8, wherein each of the joints includes a pivot housing, and a pivot shaft received in the housing such that the housing and shaft are rotatable relative to one another about the longitudinal axis of the shaft.

10. The reflective photolithography apparatus according to claim 3, wherein the control mirror module includes at least two respective electromagnets juxtaposed with each of the unit control mirrors adjacent an upper surface of the mirror substrate.

11. The reflective photolithography apparatus according to claim 10, wherein the control mirror module further includes a control device that controls the electromagnets.

12. The reflective photolithography apparatus according to claim 11, wherein the control device includes:
a MOS transistor having a gate electrode and a source electrode;
a word line and a word line driver connected to the gate electrode of the MOS transistor; and
a bit line and a bit line driver connected to the source electrode of the MOS transistor.

13. The reflective photolithography apparatus according to claim 1, further comprising a blinder interposed between the reticle stage and the illumination mirror system with respect to an optical axis of the apparatus.

14. The reflective photolithography apparatus according to claim 13, wherein the blinder comprises a plate having an exposure slit therethrough.

15. A reflective photolithography apparatus, comprising:
a light source that generates extreme ultraviolet light;
an illumination mirror system disposed in the apparatus to receive light generated by the light source and reflect the light;
a blinder disposed in the apparatus to receive the light reflected by the illumination mirror system and configured to allow one portion of the light received thereby to pass therethrough and block the remainder of the light received thereby;
a reticle stage configured to support a reflective reticle at a bottom thereof, the reticle stage being positioned relative to the blinder such that the portion of the light passing through the blinder is received by the reticle supported by the reticle stage and reflected thereby back through the blinder;
a projection mirror system disposed in the apparatus to receive the light reflected from the reflective reticle mounted on the reticle stage and passing back through the exposure slit, and project the light in a given direction in the apparatus; and
a wafer stage disposed in the apparatus in the path of the light projected by the projection mirror system such that a wafer mounted on the wafer stage will receive the light projected by the projection mirror system,
wherein the illumination mirror system includes a control mirror module at an end thereof closest to the blinder with respect to the direction in which light is transmitted from the illumination mirror system in the apparatus, the control mirror module having a plurality of unit control mirrors which divide the light so as to illuminate a number of domains, respectively, and the unit control mirrors are adjustable to vary the intensity of the light among the domains.

16. A reflective photolithography apparatus having an optical axis, and comprising:
a light source;
a reticle stage;
an optical illumination system interposed between the light source and the reticle stage along the optical axis of the apparatus so as to direct light from the light source in a direction along the optical axis towards the reticle stage;
a wafer stage; and
an optical projection system interposed between the reticle stage and the wafer stage along the optical axis of the apparatus so as to project light from a reticle mounted to the reticle stage in a direction along the optical axis towards the wafer stage whereby a reticle mounted to the reticle stage can be illuminated with light from the light source, and
wherein the optical illumination system includes a control mirror module having a control mirror substrate, and a plurality of unit control mirrors supported by the mirror substrate so as to divide the light received by the optical illumination system from the light source and reflect the light, respectively, to illuminate a number of domains, and
the unit control mirrors are adjustable to vary the intensity of the light among the domains.

17. The reflective photolithography apparatus according to claim 16, wherein the optical illumination system comprises at least one illumination mirror fixed in the apparatus along the optical apparatus, the control mirror module is disposed at an end of the optical illumination system closest to the reticle stage with respect to the optical axis.

18. The reflective photolithography apparatus according to claim 16, wherein the control mirror module includes supports that connect the unit control mirrors to the mirror substrate, the supports comprising joints that allow the unit control mirrors to tilt relative to the mirror substrate.

19. The reflective photolithography apparatus according to claim 18, wherein each of the unit control mirrors includes a unit mirror substrate comprising magnetic material, and a reflective surface, and the control mirror module has a plurality of electromagnets integrated with the control mirror substrate.

20. The reflective photolithography apparatus according to claim 18, further comprising a reflective reticle mounted to the reticle stage, wherein the light source is a source of extreme ultraviolet light, and wherein the reflective reticle includes a reticle substrate and a reticle pattern at a surface of the reticle substrate and which is reflective with respect to extreme ultraviolet light.
